(19) United States
(12) Patent Application Publication
(10) Pub. No.: US 2024/0355793 A1
(43) Pub. Date: Oct. 24, 2024

(54) SEMICONDUCTOR PACKAGE STRUCTURE

(71) Applicant: Advanced Semiconductor Engineering, Inc., Kaohsiung (TW)

(72) Inventors: Kay Stefan ESSIG, Radebeul (DE); You-Lung YEN, Taoyuan (TW); Bernd Karl APPELT, Holly Springs, NC (US); Jean Marc YANNOU, Luc-sur-Mer (FR)

(73) Assignee: Advanced Semiconductor Engineering, Inc., Kaohsiung (TW)

(21) Appl. No.: 18/137,392

(22) Filed: Apr. 20, 2023

(51) Int. Cl. H01L 25/10; H01L 23/31; H01L 23/538

(52) U.S. Cl. CPC H01L 25/105; H01L 23/3128; H01L 23/5383; H01L 23/5386; H01L 2225/1058

(57) ABSTRACT

A semiconductor package structure and a method of manufacturing a semiconductor package structure is provided. The semiconductor package structure includes a carrier and a component. The carrier includes a first part and a second part separated from the first part. The component is disposed under the first part and electrically connected to the second part. The first part is configured to be electrically connected to a device disposed over the first part.

### BACKGROUND

### 1. Field of the Disclosure

The present disclosure relates to a semiconductor package structure and a method for manufacturing the same.

### 2. Description of the Related Art

A package may include a die mounted on a carrier, and another die or system may be stacked over the die. In order to connect the upper die to the lower one, electroplated copper pillars, big solder balls, or copper pins may be additionally formed, which is not cost-effective.

### SUMMARY

In some embodiments, a semiconductor package structure includes a carrier and a component. The carrier includes a first part and a second part separated from the first part. The component is disposed under the first part and electrically connected to the second part. The first part is configured to be electrically connected to a device disposed over the first part.

In some embodiments, a semiconductor package structure includes a carrier and a component. The component is disposed under the carrier and includes a plurality of pads at an active surface of the component. The carrier includes a trace portion disposed over a backside surface of the component. The trace portion is electrically insulated from the backside surface of the component and electrically connected to the pad of the component.

In some embodiments, a semiconductor package structure includes a carrier and a component. The component is surrounded by the carrier. The carrier includes an interconnection element adjacent to the die. The interconnection element has a first tapered portion and a second tapered portion connected to the first tapered portion. The first tapered portion and the second tapered portion taper in opposite directions.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a semiconductor package structure according to some embodiments of the present disclosure.

FIG. 1A, FIG. 1B, FIG. 1C, FIG. 1D, FIG. 1E, FIG. 1F, FIG. 1G, and FIG. 1H illustrate one or more stages of an example of a method for manufacturing a semiconductor package structure according to some embodiments of the present disclosure.

FIG. 2 illustrates a cross-sectional view of a semiconductor package structure according to some embodiments of the present disclosure.

FIG. 2A and FIG. 2B illustrate one or more stages of an example of a method for manufacturing a semiconductor package structure according to some embodiments of the present disclosure.

FIG. 3 illustrates a cross-sectional view of a semiconductor package structure according to some embodiments of the present disclosure.

FIG. 3A, FIG. 3B, FIG. 3C, FIG. 3D, FIG. 3E, and FIG. 3F illustrate one or more stages of an example of a method for manufacturing a semiconductor package structure according to some embodiments of the present disclosure.

FIG. 4 illustrates a cross-sectional view of a semiconductor package structure according to some embodiments of the present disclosure.

FIG. 4A and FIG. 4B illustrate one or more stages of an example of a method for manufacturing a semiconductor package structure according to some embodiments of the present disclosure.

FIG. 5 illustrates a cross-sectional view of a semiconductor package structure according to some embodiments of the present disclosure.

FIG. 5A illustrates a cross-sectional view of a semiconductor package structure according to some embodiments of the present disclosure.

FIG. 5B, FIG. 5C, FIG. 5D, and FIG. 5E illustrate one or more stages of an example of a method for manufacturing a semiconductor package structure according to some embodiments of the present disclosure.

FIG. 6 illustrates a cross-sectional view of a semiconductor package structure according to some embodiments of the present disclosure.

FIG. 6A and FIG. 6B illustrate one or more stages of an example of a method for manufacturing a semiconductor package structure according to some embodiments of the present disclosure.

FIG. 7 illustrates a cross-sectional view of a semiconductor package structure according to some embodiments of the present disclosure.

FIG. 7A and FIG. 7B illustrate one or more stages of an example of a method for manufacturing a semiconductor package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

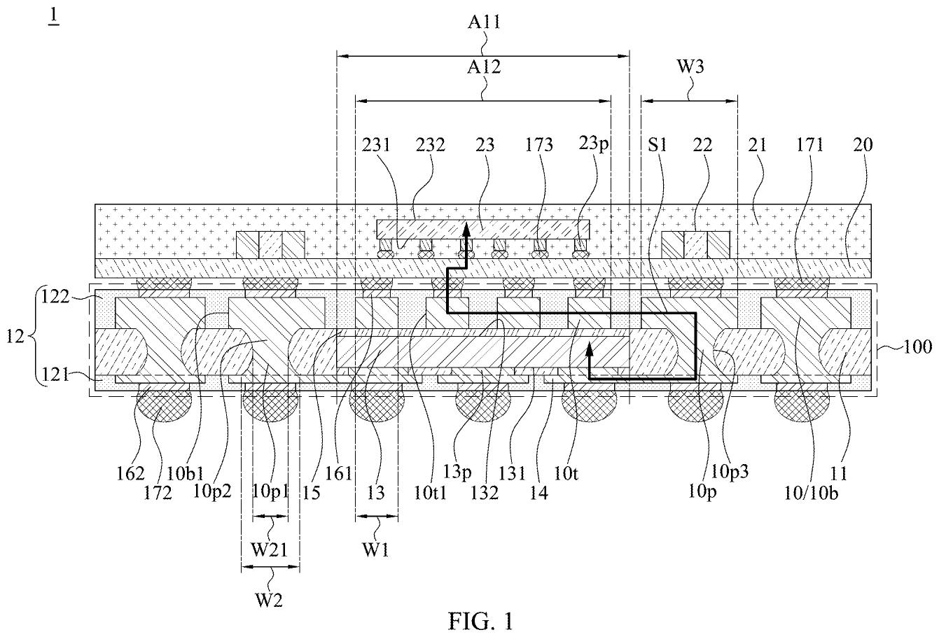

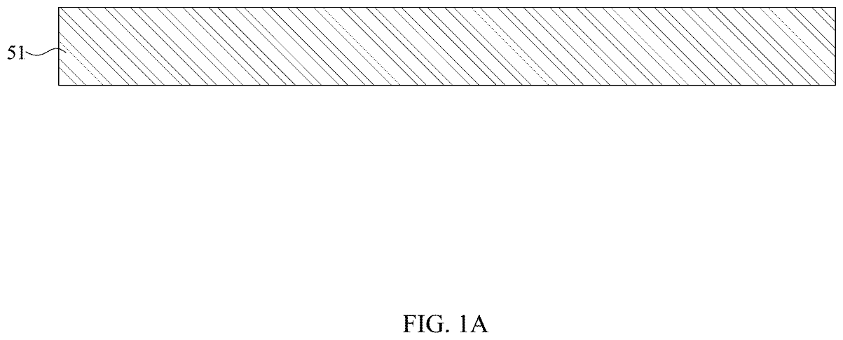

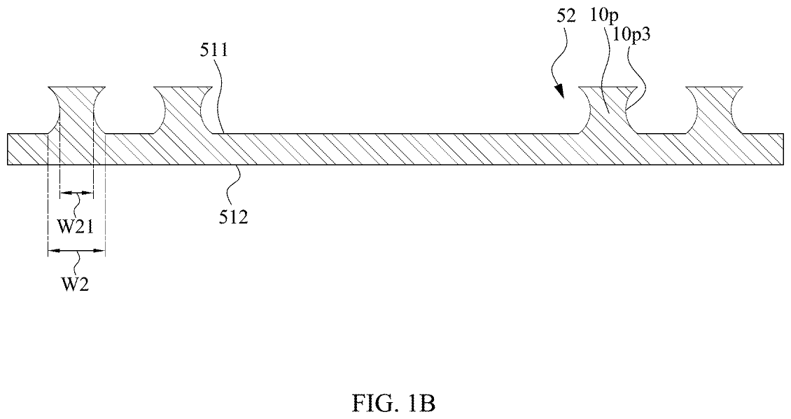

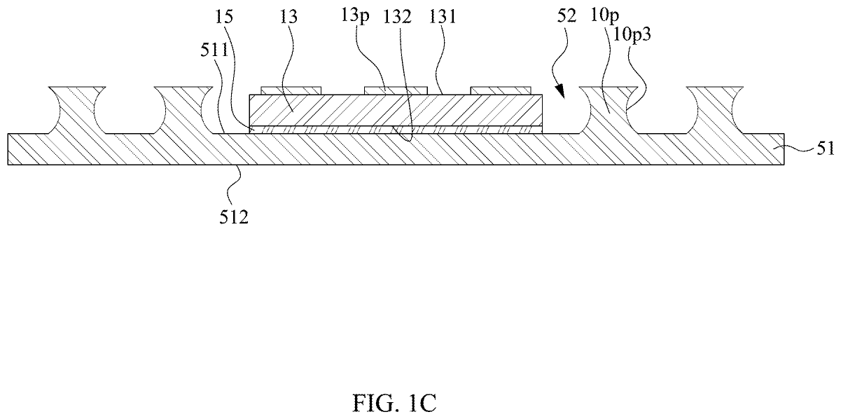

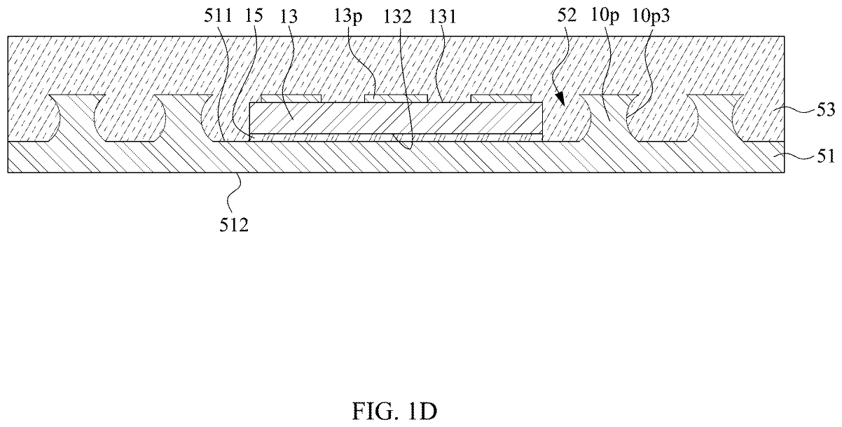

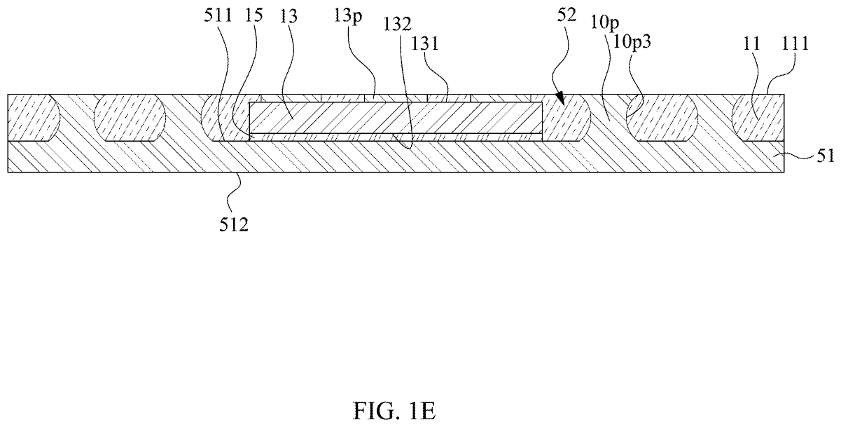

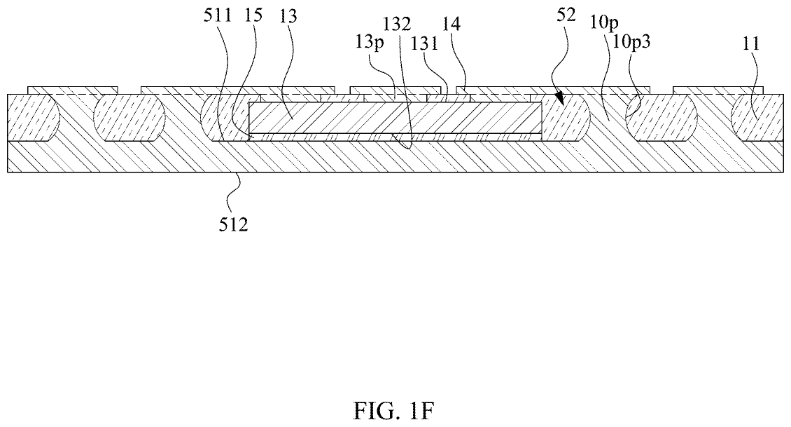

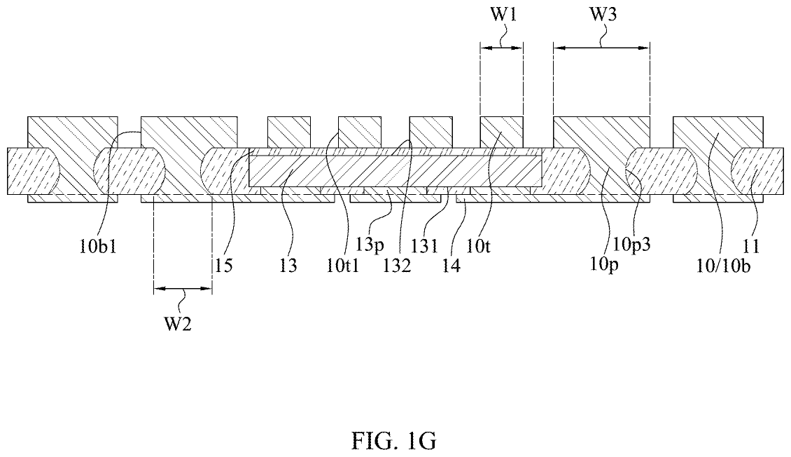

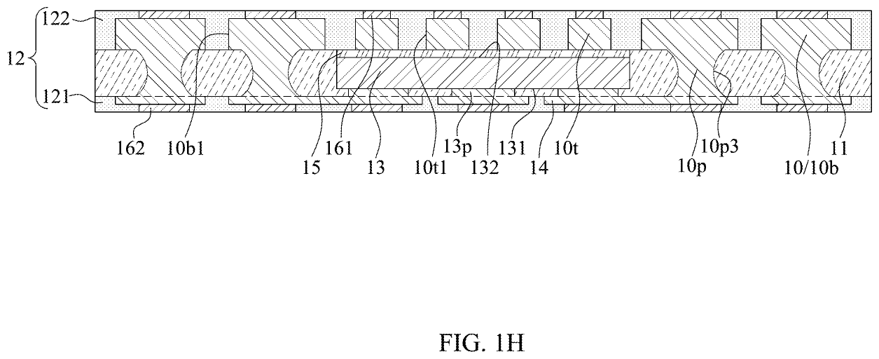

FIG. 1 illustrates a cross-sectional view of a semiconductor package structure 1 according to some embodiments of the present disclosure. The semiconductor package structure 1 may include a carrier 10, a dielectric layer 11, a protective layer 12, a component 13, a redistribution structure 14, an insulation layer 15, a plurality of conductive layers 161 and 162, and a plurality of connection elements 171 and 172.

The carrier (or a leadframe) 10 may be surrounded by or embedded in the dielectric layer 11. The dielectric layer 11 may include a single layer or a lamination layer. The material of the dielectric layer 11 may include, for example, an organic material, such as a solder mask, a polyimide (PI), an Ajinomoto build-up film (ABF), and one or more molding compounds. The material of the dielectric layer 11 may include, for example, an inorganic material silicon-oxide (SiOₓ), or a silicon-nitride (SiNₓ).

The carrier 10 may be covered by the protective layer 12. The dielectric layer 11 may be covered by the protective layer 12. The protective layer 12 may have a portion 122 disposed over the dielectric layer 11 and the other portion 121 disposed under the dielectric layer 11. The protective layer 12 may include a solder mask.

The carrier 10 may be disposed over the component 13. The component 13 may be disposed under the carrier 10. The component (or the die) 13 may be surrounded by the carrier 10. The component 13 may be surrounded by or embedded in the dielectric layer 11. The component 13 may have an active surface (or a lower surface) 131 and a backside surface (or an upper surface) 132 opposite to the active surface 131. The active surface 131 may face the redistribution structure 14 or the redistribution structure 14 may be disposed over the active surface 131. The backside surface 132 may face the trace portion 10t of the carrier 10. The component 13 may include a plurality of pads 13p disposed at the active surface 131. The pads 13p of the component 13 may be electrically connected to the active surface 131 of the component 13 (or the circuits at or adjacent to the active surface 131). The pads 13p may protrude from the active surface 131. In some embodiments, the pads 13p may be partially or completely buried in the component 13. The pads 13p may include metal or a metal alloy such as copper (Cu), gold (Au), aluminum (Al), or the alloy thereof.

The component 13 may include a semiconductor die. In some embodiments, the component 13 may include one or more processing elements at or adjacent to the active surface 131 as well as one or more memory elements at or adjacent to the active surface 131 and electrically connected to the processing elements. The processing element(s) and the memory element(s) may be divided from or originate in a monolithic processing unit (e.g., a CPU, an MPU, a GPU, an MCU, an ASIC, or the like). In some embodiments, the processing element may be a CPU chiplet, an MCU chiplet, a GPU chiplet, an ASIC chiplet, or the like.

The carrier 10 may include a base portion (or a part) 10b, a trace portion (or a part) 10t, and one or more conductive pillars (or a part) 10p. The base portion 10b, the trace portion 10t, and the conductive pillars 10p of the carrier 10 may each include metal or a metal alloy such as copper (Cu), gold (Au), aluminum (Al), or the alloy thereof. In some embodiments, the base portion 10b, the trace portion 10t, and the conductive pillars 10p of the carrier 10 may be integrally formed. In particular, the conductive pillars 10p may be formed by partial-etching the carrier 10 into a predetermined thickness. The trace portion 10t may be formed by partial-etching the carrier 10 with a predetermined pattern. The partial-etching may include a half-etching.

The base portion 10b may be connected to the trace portion 10t. The base portion 10b may around or surround the trace portion 10t. The base portion 10b and the trace portion 10t have substantially the same height. The base portion 10b may be connected to the conductive pillars 10p. The base portion 10b may be disposed over the conductive pillars 10p. The base portion 10b may be disposed over the dielectric layer 11. The base portion 10b may be surrounded by the portion 122 of the protective layer 12. The base portion 10b may not overlap the component 13 in a direction perpendicular to the backside surface 132 of the component 13.

The conductive pillars 10p may be electrically connected to the trace portion 10t through the base portion 10b. The trace portion 10t may be electrically connected to the redistribution structure 14 through the conductive pillars 10p. The conductive pillars 10p may be referred to as interconnection elements. The base portion 10b in the cross section of FIG. 1 may form a base of the conductive pillars 10p and thus may be referred to as a part of the conductive pillars 10p.

The conductive pillars 10p may be disposed in the dielectric layer 11. The conductive pillars (or the interconnection elements) 10p may be embedded in the dielectric layer 11. The conductive pillars 10p may extend through the dielectric layer 11. The conductive pillars 10p may be disposed between the portions 121 and 122 of the protective layer 12. The one or more conductive pillars 10p may be adjacent to the component 13. The conductive pillars 10p may be around the component 13. The conductive pillars 10p may extend between the trace portion 10t and the component 13 in a direction vertical to the backside surface 132 of the component 13. The conductive pillars 10p may extend between the trace portion 10t and the redistribution structure 14 in a direction vertical to the backside surface 132 of the component 13.

The conductive pillars 10p may be disposed over the redistribution structure 14. The conductive pillars 10p may be electrically connected to the redistribution structure 14. The redistribution structure 14 may include a conductive pad(s), a trace(s), a via(s), or other interconnection(s) embedded in the portion 121 of the protective layer 12. The redistribution structure 14 may not have a seed layer. In some embodiments, the redistribution structure 14 may include a seed layer in contact with the pads 13p and the conductive pillars 10p. The redistribution structure 14 may be electrically connected to the component 13 (or the pads 13p). The conductive pillars 10p may be electrically connected to the component 13 through the redistribution structure 14.

The redistribution structure 14 may be electrically connected to the plurality of connection elements 172 through the conductive layer 162. The connection elements 172 may be disposed under the redistribution structure 14. The component 13 may be electrically connected to an external system, device, or circuit (not shown) through the redistribution structure 14 and the connection elements 172. The connection elements 172 may include a solder bump. The material of the conductive layer 162 may include nickel and gold. The conductive layer 162 may include electroless Nickel immersion Gold (ENIG). The conductive layer 162 may improve the bondability of the connection elements 172. In some embodiments, there may be an intermetallic layer between the conductive layer 162 and the connection elements 172.

The conductive pillar (or the interconnection element) 10p includes a monolithic structure. The conductive pillar 10p may have a tapered portion 10p1 and a tapered portion 10p2 connected to the tapered portion 10p1. The tapered portion 10p1 and the tapered portion 10p2 may taper in opposite directions. The tapered portion 10p1 may taper in a direction toward the base portion 10b. The tapered portion 10p2 may taper in a direction toward the redistribution structure 14. The conductive pillar 10p has a double-tapering or a concave profile. The double-tapering or concave profile may be induced by the undercut effect during the etching of a conductive base to form the conductive pillar 10p. The conductive pillar 10p may have a lateral surface 10p3 along the tapered portions 10p1 and 10p2. The lateral surface 10p3 may have a concave surface. Furthermore, the lateral surface 10p3 of the conductive pillar 10p may have a curved surface or an inwardly dished surface.

The trace portion (or the part) 10t may be surrounded by the base portion 10b or the conductive pillars 10p. The base portion 10b or the conductive pillars 10p may be disposed around the trace portion 10t. The trace portion 10t may be surrounded by the portion 122 of the protective layer 12. As shown in the cross section of FIG. 1, the trace portion 10t may include a plurality of sections separated from each other. In some embodiments, one or more of the sections of the trace portion 10t may be connected in another cross section (not shown). Furthermore, the sections of the trace portion 10t may be separated from the base portion 10b or the conductive pillars 10p in the cross section of FIG. 1. However, one or more of the sections of the trace portion 10t may be connected to the base portion 10b or the conductive pillars 10p in another cross section (not shown).

The trace portion 10t (or the sections thereof) may extend in a direction away from the component 13. The trace portion 10t may extend in a direction perpendicular to the backside surface 132 of the component 13 as shown in the cross section of FIG. 1. In some embodiments, the trace portion 10t may extend in a direction parallel to the backside surface 132 of the component 13 in another cross section (not shown). In a top view corresponding to the other cross section, the trace portion 10t may include a plurality of bending sections staggered and separated from each other. The trace portion 10t may be disposed over the component 13 (or the backside surface 132). The trace portion 10t may completely overlap the backside surface 132 of the component 13 in a direction perpendicular to the backside surface 132 of the component 13. The component 13 may be disposed between the trace portion 10t and the redistribution structure 14. As shown in FIG. 1, the redistribution structure 14 has a projecting area A11 on the backside surface 132 of the component 13, and the trace portion 10t has a projecting area A12 on the backside surface 132 of the component 13. The projecting area A11 may partially overlap the projecting area A12. A pattern density of the redistribution structure 14 may be different from that of the trace portion 10t. For example, when the redistribution structure 14 is formed by an electroplating process while the trace portion 10t is formed by an etching process, the pattern density of the redistribution structure 14 may be greater than that of the trace portion 10t. Furthermore, the thickness (or the Z-height) of the trace portion 10t may be larger than that of the redistribution structure 14. The trace portion 10t may be referred to as a thick conductive pattern, when compared to the redistribution structure 14.

The trace portion 10t may have a width W1 in the cross section of FIG. 1. The conductive pillars may have a width (or the bottom width) W2 in the cross section of FIG. 1. The width W1 of the trace portion 10t may be smaller than the width W2 of the conductive pillars 10p. The conductive pillars may further have a central width W21 in the cross section of FIG. 1. The conductive pillar 10p has a double-tapering profile. In other words, the central width W21 at the middle of the conductive pillar 10p may be smaller than the bottom width W2 at the end of the conductive pillar 10p. The base portion 10b may have a width W3 in the cross section of FIG. 1. The width W1 of the trace portion 10t may be smaller than the width W3 of the base portion 10b. The width W2 of the conductive pillar 10p may be smaller than the width W3 of the base portion 10b.

The insulation layer (or adhesive layer) 15 may be disposed between the trace portion 10t and the backside surface 132 of the component 13. At least one of the sections of the trace portion 10t may be exposed from the insulation layer 15. The trace portion 10t of the carrier 10 may be free from contacting the component 13. The trace portion 10t may be electrically insulated from the backside surface 132 of the component 13 through the insulation layer 15. Given that the trace portion 10t is electrically connected to the redistribution structure 14 through the conductive pillars 10p and that the pads 13p are electrically connected to the redistribution structure 14, the trace portion 10t may be electrically connected to the pads 13p of the component 13.

The insulation layer 15 may include an adhesive layer attaching the backside surface 132 of the component 13 to the trace portion 10t of the carrier 10. The insulation layer 15 may be electrically isolated but thermally conductive. The insulation layer 15 may be beneficial to the thermal dissipation from the component 13 to the carrier 10. The insulation layer 15 may include heat dissipation gel or thermal interface material, which may include silicone, wax, polymer, or other suitable materials.

The base portion 10b may have a lateral surface 10b1 and the trace portion 10t may have a lateral surface 10t1. Given that the base portion 10b and the trace portion 10t may be formed in the same partial-etching process, the surface roughnesses of the lateral surfaces 10b1 and 10t1 may be substantially the same. As shown in FIG. 1, the lateral surfaces 10b1 and 10t1 may be flat. In some embodiments, the lateral surfaces 10b1 and 10t1 may be curved or tapered because of the partial-etching process. The extent of the curvature and tapering depends based on the etching depth or the type of etchant. The base portion 10b and the trace portion 10t of the carrier 10 may be electrically connected to the plurality of connection elements 171 through the conductive layer 161. The connection elements 171 may be disposed over the carrier 10. The connection elements 171 may include a solder bump. The material of the conductive layer 161 may include nickel and gold. The conductive layer 161 may include electroless Nickel immersion Gold (ENIG). The conductive layer 161 may improve the bondability of the connection elements 171. In some embodiments, there may be an intermetallic layer between the conductive layer 161 and the connection elements 171.

The carrier 10 (including the trace portion 10t, the base portion 10b, and the conductive pillars 10p), the dielectric layer 11, the protective layer 12, the component 13, the redistribution structure 14, and the insulation layer 15 may be collectively referred to as a semiconductor package structure 100 electrically connected to other systems, components, and devices stacked thereover. The semiconductor package structure 1 may further include a carrier 20, an encapsulant 21, a passive component 22, a component 23, and a plurality of connection elements 173. The carrier 20, the encapsulant 21, the passive component 22, a component 23, and a plurality of connection elements 173 may be collectively referred to as a package and may be stacked over and electrically connected to the semiconductor package structure 100.

The carrier 20 may be electrically connected to the semiconductor package structure 100 through the conductive pillars 10p. In the present disclosure, the trace portion 10t provides an electrical connection between the carrier 20 and the semiconductor package structure 100. As shown in FIG. 1, a transmission path S1 may be established among the component 23, the carrier 20, the trace portion 10t, the conductive pillars 10p, the redistribution structure 14, and the component 13. Referring to the electrical transmission path S1, the trace portion 10t may be configured to be electrically connected to the component 23 through the carrier 20. In addition to the conductive pillars 10p, the trace portion 10t disposed over the backside surface 132 of the component 13 increases the routing area between the semiconductor package structure 100 and the carrier 20. As such, the I/O density and the bandwidth of the semiconductor package structure 100 can be increased.

In some cases, the stacking components may be electrically connected to each other through an electroplated conductive element or a solder bump. However, the formation of the electroplated conductive element (or the solder bump) would increase the manufacturing complexity and the cost. In the present disclosure, the component 23 stacked over the component 13 can be electrically connected to the double-tapering conductive pillars 10p which are formed by a partial-etching process from the carrier 10. The formation of the partially-etched conductive pillar requires a low cost, high throughput process, and the process costs of semiconductor package structure 1 can be reduced by eliminating at least one electroplating process. Furthermore, the partial-etched conductive pillars of the present disclosure can be more reliable than the electroplated conductive element.

Furthermore, the component 13 may be configured to be electrically connected to the component 23 through the conductive pillar 10p, the redistribution structure 14, and the trace portion 10t. The redistribution structure 14 is disposed under and electrically connected to the component 23. The redistribution structure 14 and the partially-etched trace portion 10t disposed at the opposite sides of the semiconductor package structure 100 achieve the heterogeneous integration of the high pattern density fan-out redistribution structure and the thick conductive pattern.

The carrier 20 may be electrically connected to a plurality of pads 23p of the component 23 through the connection elements 173. The carrier 20 may be electrically connected to the passive component 22. The carrier 20, the passive component 22, and the component 23 may be covered by the encapsulant 21.

The carrier 20 may include an interposer. In some embodiments, the carrier 20 may include, for example, a printed circuit board (PCB), such as a paper-based copper foil laminate, a composite copper foil laminate, or a polymer-impregnated glass-fiber-based copper foil laminate. The encapsulant 21 may include an epoxy resin including fillers, a molding compound (e.g., an epoxy molding compound or another molding compound), polyimide, a phenolic compound or material, a material including silicone dispersed therein, or a combination thereof. The passive component 22 may include a resistor, capacitor, inductor, or the like. The component 23 may include a semiconductor die. In some embodiments, the component 23 may include one or more processing elements and one or more memory elements electrically connected to the processing elements. The processing element(s) and the memory element(s) may be divided from or originate in a monolithic processing unit (e.g., a CPU, an MPU, a GPU, an MCU, an ASIC, or the like). In some embodiments, the processing element may be a CPU chiplet, an MCU chiplet, a GPU chiplet, an ASIC chiplet, or the like.

FIG. 1A, FIG. 1B, FIG. 1C, FIG. 1D, FIG. 1E, FIG. 1F, FIG. 1G, and FIG. 1H illustrate one or more stages of an example of a method for manufacturing a semiconductor package structure (e.g., the semiconductor package structure 1) according to some embodiments of the present disclosure.

Referring to FIG. 1A, a conductive base 51 is provided. The conductive base 51 may include metal or a metal alloy such as copper (Cu), gold (Au), aluminum (Al), or the alloy thereof.

Referring to FIG. 1B, the conductive base 51 may be partially etched to form a surface 511 and a plurality of conductive pillars (or interconnection elements) 10p. The partial-etching may include half-etching. The conductive base 51 may have a surface 512 opposite to the surface 511. The conductive pillars 10p may have a lateral surface 10p3. The surface 511 may be substantially flat surface or may be a curved surface. Owing to the undercut effect of the partially etching process, the lateral surface 10p3 may have at least two portions tapering in opposite directions. The conductive pillar 10p has a double-tapering or a concave profile. The lateral surface 10p3 may have concave surface, inwardly dished surface, or curved surface. In some embodiments, if the etching depth is shorter, the undercut effect may be relatively small and the conductive pillar 10p may have a single-tapering shape. A central width W21 of the conductive pillar 10p may be smaller than a bottom width W2 of the conductive pillar 10p. The surface 511 of the conductive base 51 and the lateral surfaces 10p3 of the conductive pillars 10p define a space 52.

Referring to FIG. 1C, a component (or a die) 13 may be attached to (or bonded on) the surface 511 of the conductive base 51 through an adhesive layer (or an insulation layer) 15. The component 13 is within the space 52. The component 13 has an active surface 131 and a backside surface 132. The backside surface 132 faces the surface 511 of the conductive base 51. The component 13 may include a plurality of pads 13p at the active surface 131.

Regarding to FIG. 1D, a dielectric material 53 is formed on the conductive base 51 to encapsulate the conductive pillars 10p and the component 13. The dielectric material 53 may include a single layer or a lamination layer. The dielectric material 53 may include, for example, an organic material, such as a solder mask, a polyimide (PI), an Ajinomoto build-up film (ABF), and one or more molding compounds. The dielectric material 53 may include, for example, an inorganic material silicon-oxide (SiOₓ), or a silicon-nitride (SiNₓ).

Referring to FIG. 1E, the dielectric material 53 is grinded to form a dielectric layer 11 having a surface 111 facing away from the conductive base 51. The surface 111 of the dielectric layer 11, an upper surface of the conductive pillar 10p, and/or an upper surface of the pads 13p are substantially coplanar.

Referring to FIG. 1F, a redistribution structure 14 may be formed over the pads 13p of the component 13, the conductive pillars 10p, and the dielectric layer 11. The redistribution structure 14 may be formed by an electroplating process. The redistribution structure 14 may be electrically connected to the pads 13p of the component 13 and the conductive pillars 10p. In some embodiments, the redistribution structure 14 may not have a seed layer. In some embodiments, the redistribution structure 14 may include a seed layer contacting the pads 13p of the component 13, the conductive pillars 10p, and the dielectric layer 11.

Referring to FIG. 1G, the conductive base 51 is partially etched from the surface 512 to form a base portion 10b over the conductive pillar 10p and a trace portion 10t over the backside surface 132 of the component 13. The base portion 10b, the trace portion 10t, and the conductive pillars 10p may be referred to as a carrier 10. A lateral surface 10t1 of the trace portion 10t and a lateral surface 10b1 of the base portion 10b may be flat. In some embodiments, the lateral surfaces 10t1 and 10b1 of the trace portion 10t and the base portion 10b may be curved or tapered because of the partial-etching process. The extent of the curvature and tapering depends based on the etching depth or the type of etchant. The trace portion 10t may include a plurality of sections separated from each other in the cross section of FIG. 1G. In some embodiments, one or more of the sections of the trace portion 10t may be connected. The trace portion 10t may be separated from the base portion 10b in the cross section of FIG. 1G. The trace portion 10t may be connected to the base portion 10b in another cross section. The base portion 10b may be connected to the conductive pillars 10p. A width W1 of the trace portion 10t may be smaller than the width W2 of the conductive pillar 10p. The width W1 of the trace portion 10t may be smaller than a width W3 of the base portion 10b.

Referring to FIG. 1H, a portion 121 of a protective layer 12 is formed on the redistribution structure 14 and the other portion 122 of the protective layer 12 is formed on the trace portion 10t and the base portion 10b of the carrier 10 to form a semiconductor package structure 100 as shown in FIG. 1. A conductive layer 161 may be formed on the trace portion 10t and the base portion 10b. A conductive layer 162 may be formed on the redistribution structure 14. The conductive layers 161 and 162 may be surrounded by the protective layer 12.

Afterwards, a carrier 20 provided with an encapsulant 21, a passive component 22, and a component 23 may be bonded on the trace portion 10t and the base portion 10b of the carrier 10 to form a semiconductor package structure 1 as shown in FIG. 1. Furthermore, a plurality of connection elements 172 may be formed on the conductive layer 162.

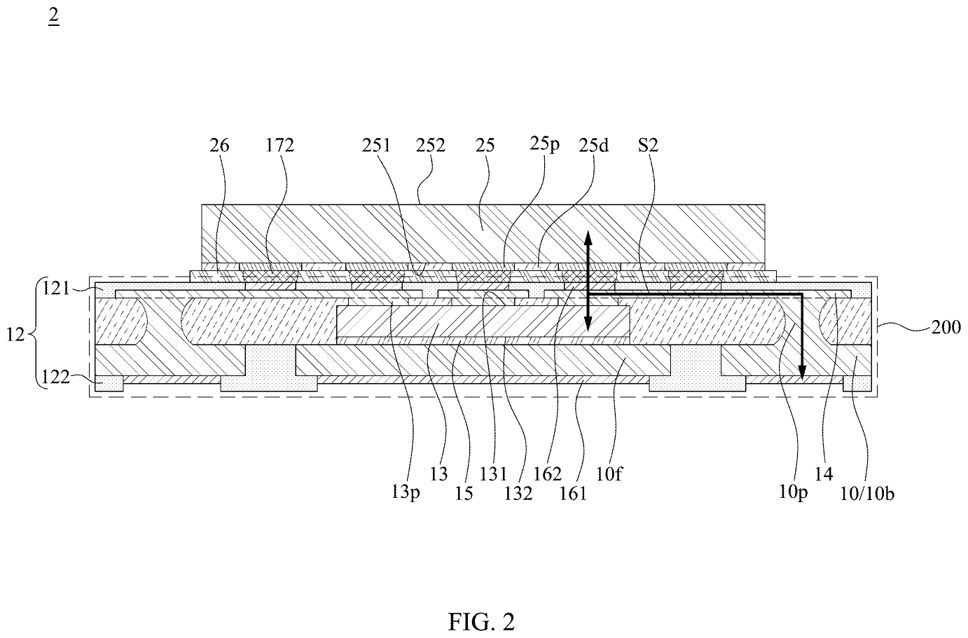

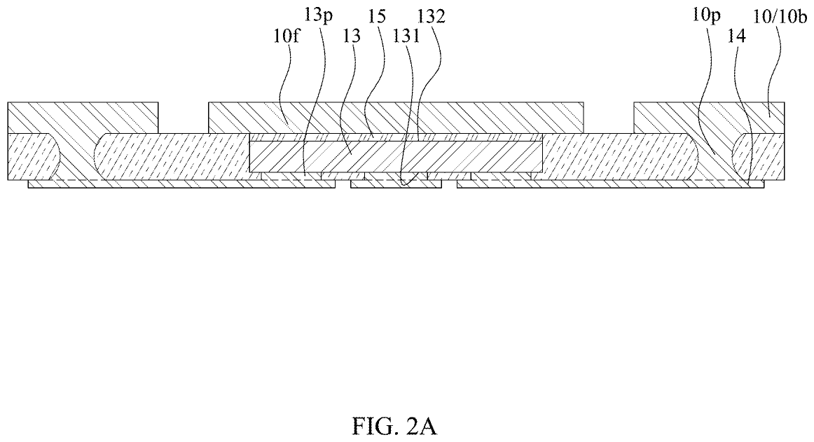

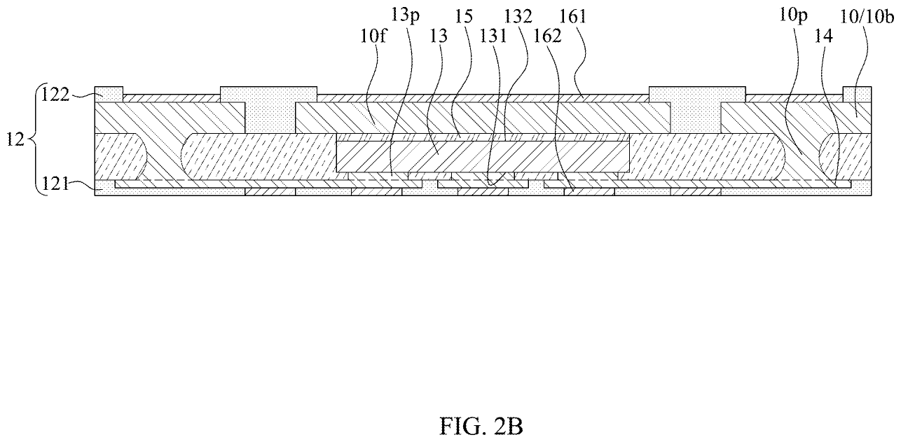

FIG. 2 is a cross-sectional view of a semiconductor package structure 2 in accordance with some embodiments of the present disclosure. The semiconductor package structure 2 in FIG. 2 is similar to the semiconductor package structure 1 in FIG. 1. Therefore, some detailed descriptions may refer to corresponding preceding paragraphs and are not repeated hereinafter for conciseness, with differences therebetween as follows.

The semiconductor package structure 2 may include a landing portion 10f disposed over the backside surface 132 of the component 13, rather than the trace portion 10t of FIG. 1. The landing portion 10f may be wider than the backside surface 132 of the component 13. The landing portion 10f may be connected to a land grid array (LGA) of an external substrate (not shown). The carrier 10 (including the landing portion 10f, the base portion 10b, and the conductive pillars 10p), the dielectric layer 11, the protective layer 12, the component 13, the redistribution structure 14, and the insulation layer 15 may be collectively referred to as a semiconductor package structure 200 electrically connected to other systems, components, and devices stacked thereover.

The semiconductor package structure 2 further includes a wafer level chip 25 stacked over the semiconductor package structure 200. In some embodiments, the wafer level chip 25 may include a single die, strip of dies, or a passive component. The wafer level chip 25 may have a plurality of input/outputs (I/Os) with a fine pitch. Thus, the redistribution structure 14 of the semiconductor package structure 2 may be electrically connected to a wafer level chip 25 through the connection elements 172. An electrical transmission path S2 may be established among the wafer level chip 25, the redistribution structure 14, the component 13, and the conductive pillars 10p. The wafer level chip 25 may be electrically connected to the component 13 through the redistribution structure 14. In some embodiments, the wafer level chip 25 may be electrically connected to an external substrate through the conductive pillars 10p and the landing portion 10f.

In the present disclosure, the wafer level chip 25 stacked over the component 13 can be electrically connected to the double-tapering conductive pillars 10p which are formed by a partial-etching process from the carrier 10. The formation of the partially-etched conductive pillar requires a low cost, high throughput process, and the process costs of semiconductor package structure 2 can be reduced by eliminating at least one electroplating process. Furthermore, the partial-etched conductive pillars of the present disclosure can be more reliable than the electroplated conductive element.

The semiconductor package structure 2 further includes an encapsulant 26 disposed between the wafer level chip 25 and the carrier 10 and surrounding the connection elements 172. The wafer level chip 25 may have an active surface 251 and a backside surface 256 opposite to the active surface 251. The active surface 251 may face the carrier 10. The wafer level chip 25 may include a plurality of pads 25p and a dielectric layer 25d surrounding the pads 25p. The pads 25p are electrically connected to the connection elements 172.

FIG. 2A and FIG. 2B illustrate one or more stages of an example of a method for manufacturing a semiconductor package structure (e.g., the semiconductor package structure 2) according to some embodiments of the present disclosure. The stages of the method for manufacturing the semiconductor package structure 2 may include the stages as illustrated in FIGS. 1A, 1B, 1C, 1D, 1E, and 1F. The stages of FIG. 2A and FIG. 2B may follow the stages of FIGS. 1A, 1B, 1C, 1D, 1E, and 1F.

Referring to FIG. 2A, the conductive base 51 is etched from the surface 512 to form a base portion 10b over the conductive pillar 10p and a landing portion 10f over the backside surface 132 of the component 13. The base portion 10b, the landing portion 10f, and the conductive pillars 10p may be referred to as a carrier 10. The landing portion 10f may be separated from the base portion 10b in the cross section of FIG. 2A. The landing portion 10f may be connected to the base portion 10b in another cross section. The base portion 10b may be connected to the conductive pillars 10p.

Referring to FIG. 2B, a portion 121 of a protective layer 12 is formed on the redistribution structure 14, and the other portion 122 of the protective layer 12 is formed on the landing portion 10f and the base portion 10b of the carrier 10 to form a semiconductor package structure 200 as shown in FIG. 2. A conductive layer 161 may be formed on the landing portion 10f and the base portion 10b. A conductive layer 162 may be formed on the redistribution structure 14. The conductive layers 161 and 162 may be surrounded by the protective layer 12.

Afterwards, a wafer level chip 25 may be bonded on the redistribution structure 14 through a plurality of connection elements 172, and an encapsulant 26 may be formed to surround the connection elements 172 to form a semiconductor package structure 2 as shown in FIG. 2.

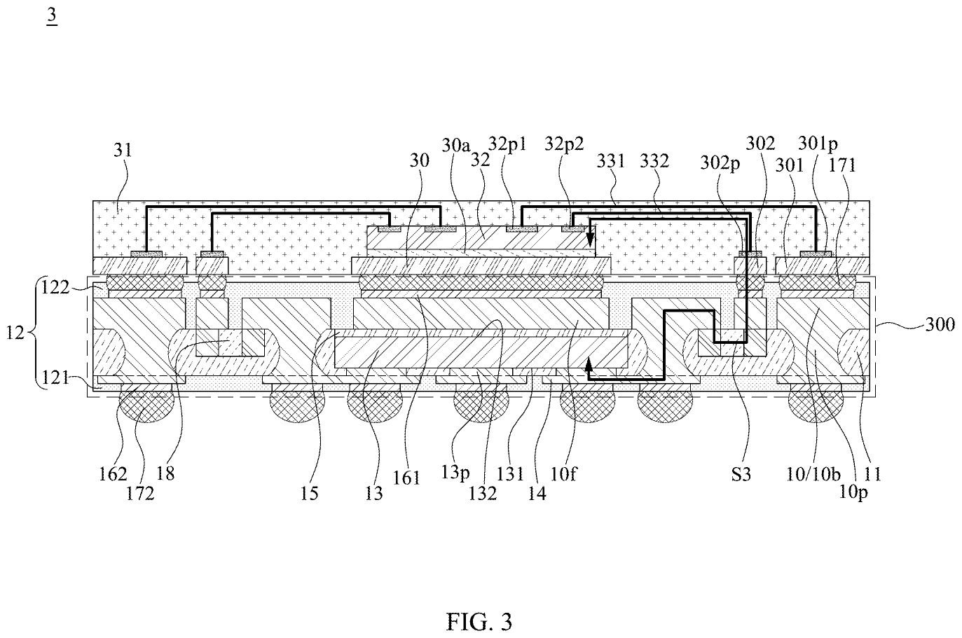

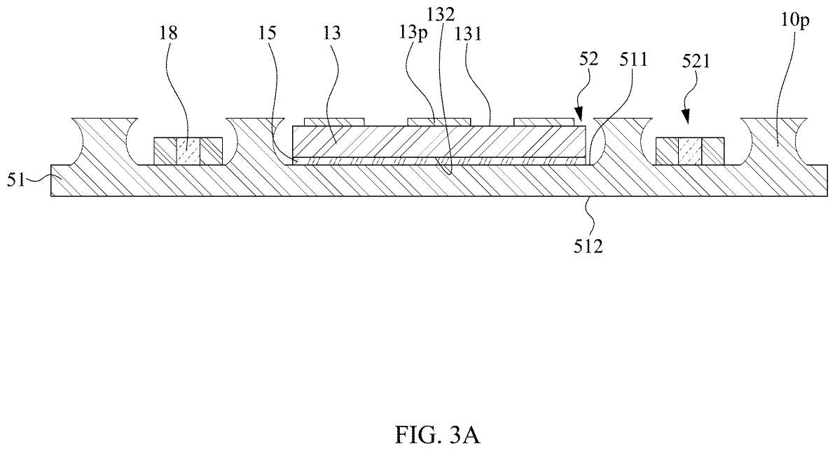

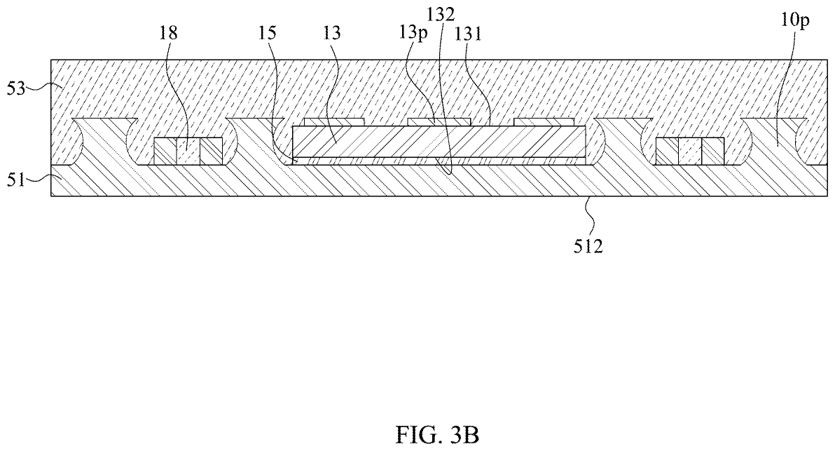

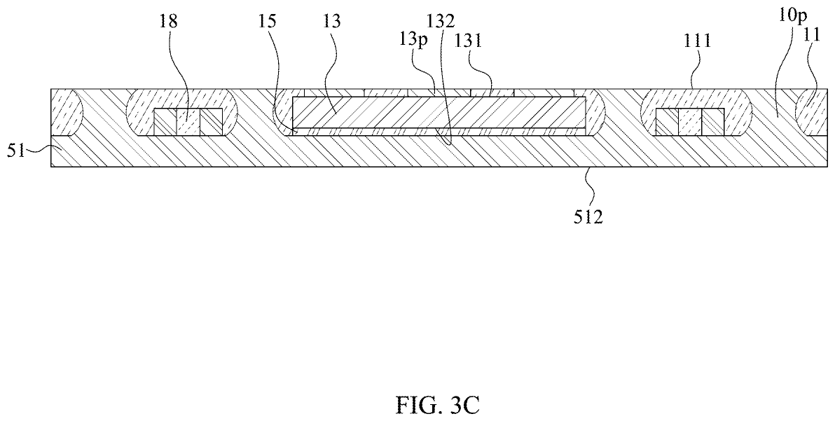

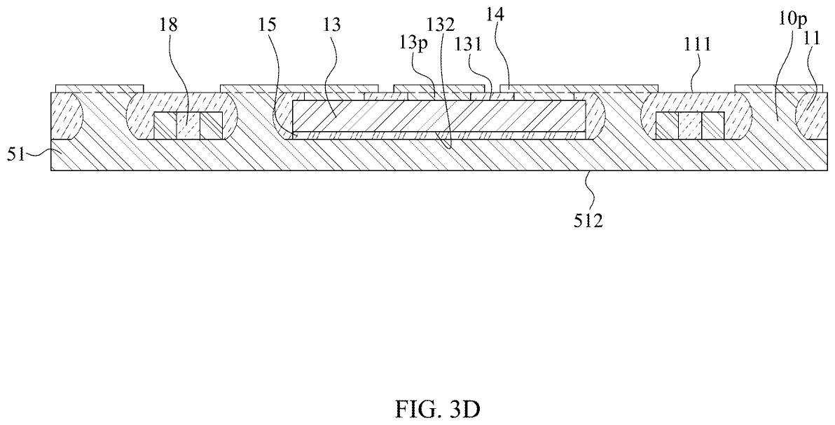

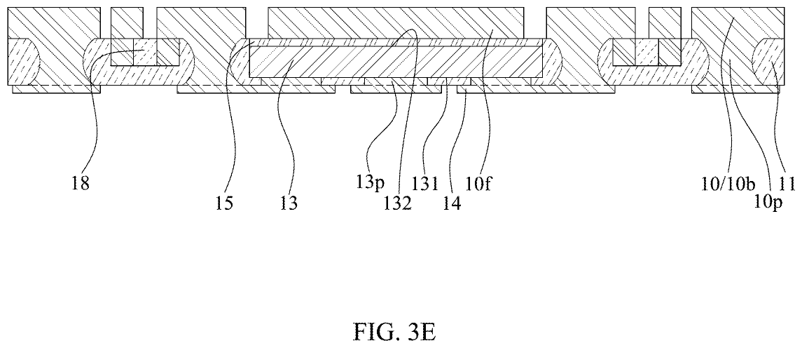

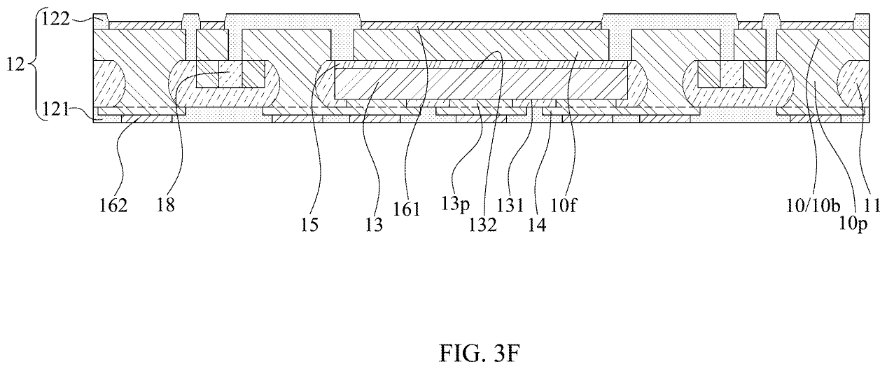

FIG. 3 illustrates a cross-sectional view of a semiconductor package structure 3 according to some embodiments of the present disclosure. The semiconductor package structure 3 in FIG. 3 is similar to the semiconductor package structure 1 in FIG. 1. Therefore, some detailed descriptions may refer to corresponding preceding paragraphs and are not repeated hereinafter for conciseness, with differences therebetween as follows.

The semiconductor package structure 3 may include a landing portion 10f disposed over the backside surface 132 of the component 13, rather than the trace portion 10t of FIG. 1. The landing portion 10f may be narrower than the backside surface 132 of the component 13. In some embodiments, the landing portion 10f may be wider than or the same as the backside surface 132 of the component 13. The landing portion 10f may be connected to a land grid array (LGA) on an external substrate. The semiconductor package structure 3 further includes a passive component 18 disposed under the base portion 10b. The passive component 18 may be surrounded by the carrier 10. The passive component 18 may be disposed between the conductive pillars 10p. The passive component 18 may be spaced apart from the component 13 by at least one of the conductive pillars 10p. The carrier 10 (including the landing portion 10f, the base portion 10b, and the conductive pillars 10p), the dielectric layer 11, the protective layer 12, the component 13, the redistribution structure 14, the insulation layer 15, and the passive component 18 may be collectively referred to as a semiconductor package structure 300 electrically connected to other systems, components, and devices stacked thereover.

The semiconductor package structure 3 further includes a carrier 30 and a component 32 stacked over the semiconductor package structure 300. The carrier 30 may include a body portion attached to the landing portion 10f of the carrier 10 through the connection element 171. The component 32 may have a lower surface attached to the body portion of the carrier 30 through an adhesive layer 30a. The carrier 30 may include pin portions 301 and 302 attached to the base portion 10b of the carrier 10 through the connection element 171. The semiconductor package structure 3 may include a plurality of wirings 331 and 332. The wirings 331 and 332 may include a bond wiring. The semiconductor package structure 3 further includes an encapsulant 31 covering the carrier 30, the component 32, and the wirings 331 and 332.

The component 32 may include pads 32p1 and 32p2 disposed at an upper surface of the component 32. The pin portion 301 may include a pad 301p and the pin portion 302 may include a pad 302p. The pad 32p1 of the component 32 may be connected to the pad 301p of the pin portion 301 through the wiring 331. The pad 32p2 of the component 32 may be connected to the pad 302p of the pin portion 302 through the wiring 332.

The component 32 may be electrically connected to the semiconductor package structure 300 through the pin portions 301 and 302. An electrical transmission path S3 may be established among the component 32, the wiring 331, the carrier 30 (including the pin portion 301), the carrier (including the base portion 10b and the conductive pillar 10p), the passive component 18, the redistribution structure 14, and the component 13. The component 32 may be electrically connected to the component 13 through the base portion 10b, the conductive pillar 10p, and the redistribution structure 14. The component 32 may be electrically connected to the component 13 through the passive component 18. The passive component 18 may have a terminal connected to the base portion 10b and the other terminal connected to the conductive pillar 10p. The passive component 18 may be configured to filter the noise of the transmitted electrical signals between the components 13 and 32. The component 32, the carrier 30, and the passive component 18 may be collectively referred to as a system in package.

In the present disclosure, the component 32 stacked over the component 13 can be electrically connected to the double-tapering conductive pillars 10p which are formed by a partial-etching process from the carrier 10. The formation of the partially-etched conductive pillar requires a low cost, high throughput process, and the process costs of semiconductor package structure 3 can be reduced by eliminating at least one electroplating process. Furthermore, the partial-etched conductive pillars of the present disclosure can be more reliable than the electroplated conductive element.

FIG. 3A, FIG. 3B, FIG. 3C, FIG. 3D, FIG. 3E, and FIG. 3F illustrate one or more stages of an example of a method for manufacturing a semiconductor package structure (e.g., a semiconductor package structure 3) according to some embodiments of the present disclosure. The stages of the method for manufacturing the semiconductor package structure 3 may include the stages as illustrated in FIGS. 1A and 1B. The stages of FIG. 3A, FIG. 3B, FIG. 3C, FIG. 3D, FIG. 3E, and FIG. 3F may follow the stages of FIGS. 1A and 1B.

Referring to FIG. 3A, a component (or a die) 13 may be attached to the surface 511 of the conductive base 51 through an adhesive layer (or an insulation layer) 15. A passive component 18 may be attached to the surface 511 of the conductive base 51. The component 13 is within the space 52. The passive component 18 is within a space 521 between the conductive pillars 10p. The component 13 has an active surface 131 and a backside surface 132. The backside surface 132 faces the surface 511 of the conductive base 51. The component 13 may include a plurality of pads 13p at the active surface 131.

Regarding to FIG. 3B, a dielectric material 53 is formed on the conductive base 51 to encapsulate the conductive pillars 10p, the component 13, and the passive component 18. The dielectric material 53 may include a single layer or a lamination layer. The dielectric material 53 may include, for example, an organic material, such as a solder mask, a polyimide (PI), an Ajinomoto build-up film (ABF), and one or more molding compounds. The dielectric material 53 may include, for example, an inorganic material silicon-oxide (SiOₓ), or a silicon-nitride (SiNₓ).

Referring to FIG. 3C, the dielectric material 53 is grinded to form a dielectric layer 11 having a surface 111 away from the conductive base 51. The surface 111 of the dielectric layer 11, an upper surface of the conductive pillar 10p, and/or an upper surface of the pads 13p are substantially coplanar. The passive component 18 may be covered by the dielectric layer 11.

Referring to FIG. 3D, a redistribution structure 14 may be formed over the pads 13p of the component 13, the conductive pillars 10p, and the dielectric layer 11. The redistribution structure 14 may be formed by an electroplating process. The redistribution structure 14 may be electrically connected to the pads 13p of the component 13 and the conductive pillars 10p. The redistribution structure 14 may not have a seed layer. In some embodiments, the redistribution structure 14 may include a seed layer contacting the pads 13p of the component 13, the conductive pillars 10p, and the dielectric layer 11.

Referring to FIG. 3E, the conductive base 51 is etched from the surface 512 to form a base portion 10b over the conductive pillar 10p and a landing portion 10f over the backside surface 132 of the component 13. The base portion 10b, the landing portion 10f, and the conductive pillars 10p may be referred to as a carrier 10. The passive component 18 may be configured to electrically connect to the base portion 10b and the conductive pillar 10p. The passive component 18 may have a terminal connected to a section of the base portion 10b and the other terminal connected to another section of the base portion 10b that connects the conductive pillar 10p.

Referring to FIG. 3F, a portion 121 of a protective layer 12 is formed on the redistribution structure 14 and the other portion 122 of the protective layer 12 is formed on the landing portion 10f and the base portion 10b of the carrier 10 to form a semiconductor package structure 300 as shown in FIG. 3. A conductive layer 161 may be formed on the landing portion 10f and the base portion 10b. A conductive layer 162 may be formed on the redistribution structure 14. The conductive layers 161 and 162 may be surrounded by the protective layer 12.

Afterwards, a carrier 30 provided with an encapsulant 31, a component 32, a plurality of wirings 331 and 3323 may be bonded on the landing portion 10f and the base portion 10b of the carrier 10 to form a semiconductor package structure 3 as shown in FIG. 3. Furthermore, a plurality of connection elements 172 may be formed on the conductive layer 162.

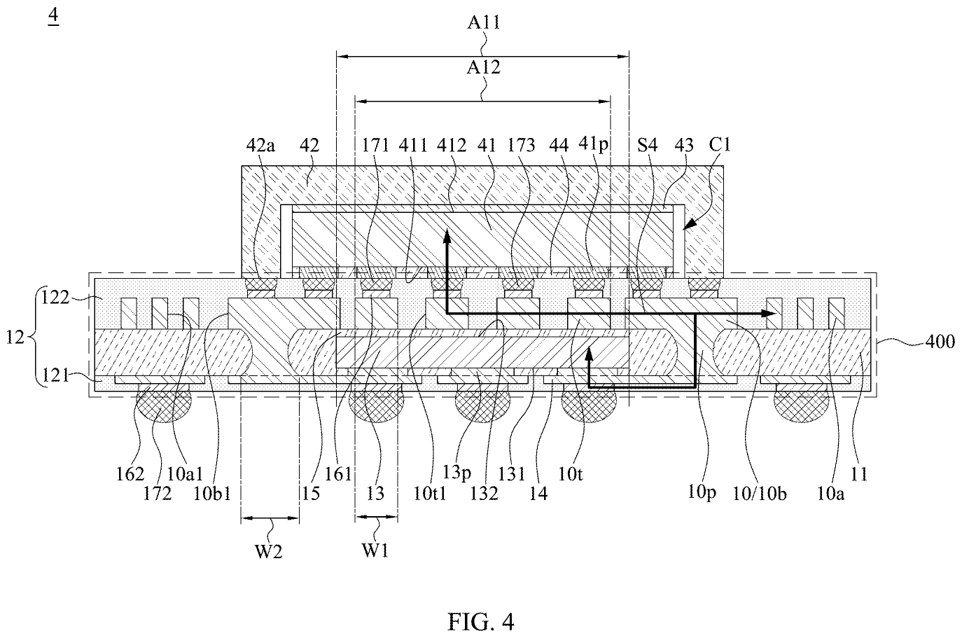

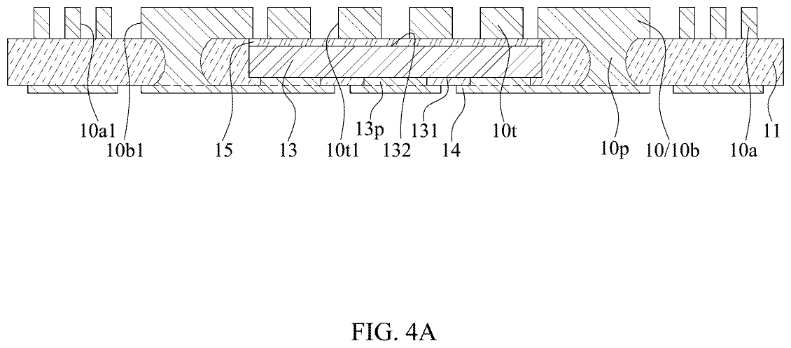

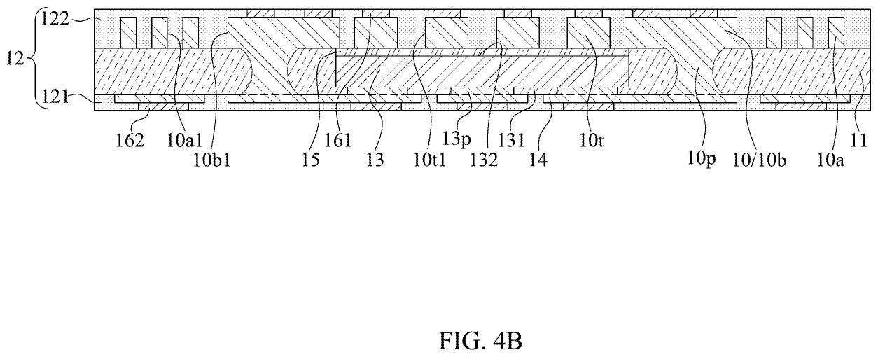

FIG. 4 illustrates a cross-sectional view of a semiconductor package structure 4 according to some embodiments of the present disclosure. The semiconductor package structure 4 in FIG. 4 is similar to the semiconductor package structure 1 in FIG. 1. Therefore, some detailed descriptions may refer to corresponding preceding paragraphs and are not repeated hereinafter for conciseness, with differences therebetween as follows.

The carrier 10 of the semiconductor package structure 4 may further include an antenna pattern (or a part of the carrier 10) 10a separated from the trace portion 10t. In some embodiments, the base portion 10b, the trace portion 10t, the conductive pillars 10p, and the antenna pattern 10a of the carrier 10 may be integrally formed. In particular, the conductive pillars 10p may be formed by partial-etching the carrier 10 into a predetermined thickness. The trace portion 10t and the antenna pattern 10a may be formed by partial-etching the carrier 10 with a predetermined pattern. A lateral surface 10t1 of the trace portion 10t and a lateral surface 10al of the antenna pattern 10a of the carrier 10 have substantially the same roughness.

The antenna pattern 10a may be configured to receive or transmit a radiation signal. The conductive pillar 10p may be disposed between the trace portion 10t and the antenna pattern 10a. The conductive pillar 10p may be configured to function as a shielding structure. As such, that radiation signal of the antenna pattern 10a may not interfere with the trace portion 10t.

Forming the antenna pattern 10a by partial-etching the carrier 10 efficiently utilizes the side rail of the carrier. As such, the size of the semiconductor package structure 4 capable of receiving and transmitting a radiation signal can be relatively small.

The antenna pattern 10a may be disposed over the conductive pillars 10p. The base portion 10b may be disposed between the antenna pattern 10a and the trace portion 10t. The antenna pattern 10a may be connected to the base portion 10b in another cross section. The antenna pattern 10a may be disposed over the dielectric layer 11. The antenna pattern 10a may be surrounded by the portion 122 of the protective layer 12. The antenna pattern 10a may be electrically connected to the component 13 through, e.g., the conductive pillars 10p and the redistribution structure 14. The antenna pattern 10a may be non-overlapping with the component 13 in a direction vertical to the backside surface 132 of the component 13. In the cross section of FIG. 4, the antenna pattern 10a may include a plurality of sections separated from each other. In another cross section, one or more of the sections of the antenna pattern 10a may be connected. In some embodiments, the antenna pattern 10a may include a patch antenna or a spiral antenna.

The carrier 10 (including the trace portion 10t, the base portion 10b, the conductive pillars 10p, and the antenna pattern 10a), the dielectric layer 11, the protective layer 12, the component 13, the redistribution structure 14, and the insulation layer 15 may be collectively referred to as a semiconductor package structure 400 electrically connected to other systems, components, and devices stacked thereover. The semiconductor package structure 4 may further include a device 41 and a metal lid 42. The device 41 and the metal lid 42 may be collectively referred to as a package and may be stacked over and electrically connected to the semiconductor package structure 400.

The trace portion 10t may be configured to be electrically connected to the device 41 disposed over the trace portion 10t. The device 41 may have an active surface (or a lower surface) 411 and a backside surface (or an upper surface) 412 opposite to the active surface 411. The device 41 may include a plurality of pads 41p surrounded by an encapsulant 44 and electrically connected to the carrier 10 (the trace portion 10t and/or conductive pillar 10p). An electrical transmission path S4 may be established among the device 41, the carrier (including the trace portion 10t, the conductive pillar 10p, and the antenna pattern 10a), the redistribution structure 14, and the component 13. The device 41 may be electrically connected to the component 13 through the trace portion 10t, the conductive pillars 10p, and the redistribution structure 14. The redistribution structure 14 is disposed under and electrically connected to the device 41. The antenna pattern 10a may be electrically connected to the device 41. The device 41 may include one or more processing units configured to process the radiation signal from the antenna pattern 10a. In some embodiments, the device 41 may include a radio frequency device. The antenna pattern 10a may be non-overlapping with the device 41 in a direction vertical to the backside surface 132 of the component 13.

The metal lid 42 and the carrier 10 may collectively define a cavity C1 for accommodating the device 41. The conductive pillar 10p may be electrically connected to the metal lid 42 disposed over the trace portion 10t. The metal lid 42 may be configured to function as a shielding structure for the device 41. As such, the device 41 may not be interfered with unwanted radiation signals from an external environment. The metal lid 42 may be attached to the carrier 10 through an adhesive layer 42a. The metal lid 42 may be applied with a reference voltage (or a grounding voltage) through at least one of the conductive pillars 10p.

Furthermore, the metal lid 42 may be attached to the surface 412 of the device 41 through an adhesive material 43. The adhesive material 43 may be or include thermal interface material (TIM). The adhesive material 43 may include a conductive glue, such as tin-based glue. The metal lid 42 may function as a heat sink or connect to a further heat sink. The metal lid (or the heat sink) 42 may be thermally connected to the device 41. The metal lid 42 may be configured to dissipate heat from the semiconductor package structure 4. In particular, the metal lid 42 may dissipate heat from the device 41 through the adhesive material 43.

In some embodiments, the semiconductor package structure 4 may include a passive component (not shown, but is similar to the passive component 18) disposed under and electrically connected to the conductive pillar 10p and the antenna pattern 10a.

FIG. 4A and FIG. 4B illustrate one or more stages of an example of a method for manufacturing a semiconductor package structure (e.g., the semiconductor package structure 4) according to some embodiments of the present disclosure. The stages of the method for manufacturing the semiconductor package structure 4 may include the stages as illustrated in FIGS. 1A, 1B, 1C, 1D, 1E, and 1F. The stages of FIG. 4A and FIG. 4B may follow the stages of FIGS. 1A, 1B, 1C, 1D, 1E, and 1F.

Referring to FIG. 4A, the conductive base 51 is etched from the surface 512 to form a base portion 10b over the conductive pillar 10p, a trace portion 10t over the backside surface 132 of the component 13, and an antenna pattern 10a. The antenna pattern 10a and the trace portion 10t may be formed concurrently. The base portion 10b, the trace portion 10t, the conductive pillars 10p, and the antenna pattern 10a may be referred to as a carrier 10. The trace portion 10t may include a plurality of sections separated from each other in the cross section of FIG. 4A. In some embodiments, one or more of the sections of the trace portion 10t may be connected. The trace portion 10t may be separated from the base portion 10b in the cross section of FIG. 4A. The trace portion 10t may be connected to the base portion 10b in another cross section. The base portion 10b may be connected to the conductive pillars 10p. The antenna pattern 10a may be further from the trace portion 10t than the base portion 10b. The conductive pillar 10p may be disposed between the trace portion 10t and the antenna pattern 10a.

Referring to FIG. 4B, a portion 121 of a protective layer 12 is formed on the redistribution structure 14, and the other portion 122 of the protective layer 12 is formed on the trace portion 10t, the base portion 10b, and the antenna pattern 10a of the carrier 10 to form a semiconductor package structure 400 as shown in FIG. 4. A conductive layer 161 may be formed on the trace portion 10t and the base portion 10b. A conductive layer 162 may be formed on the redistribution structure 14. The conductive layers 161 and 162 may be surrounded by the protective layer 12.

Afterwards, a device 41 and a metal lid 42 may be bonded on the trace portion 10t and the conductive pillars 10p of the carrier 10 to form a semiconductor package structure 4 as shown in FIG. 4. Furthermore, a plurality of connection elements 172 may be formed on the conductive layer 162.

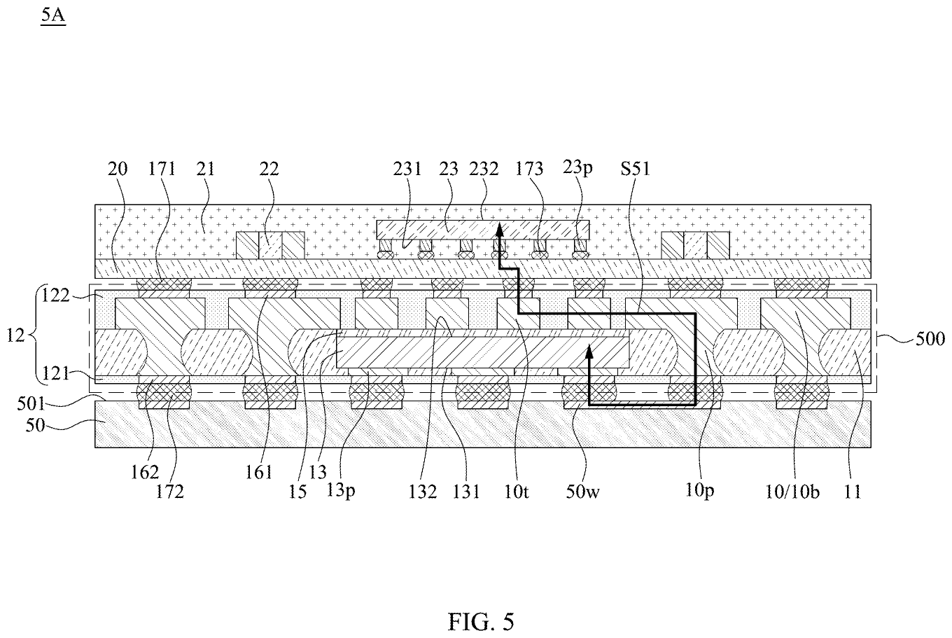

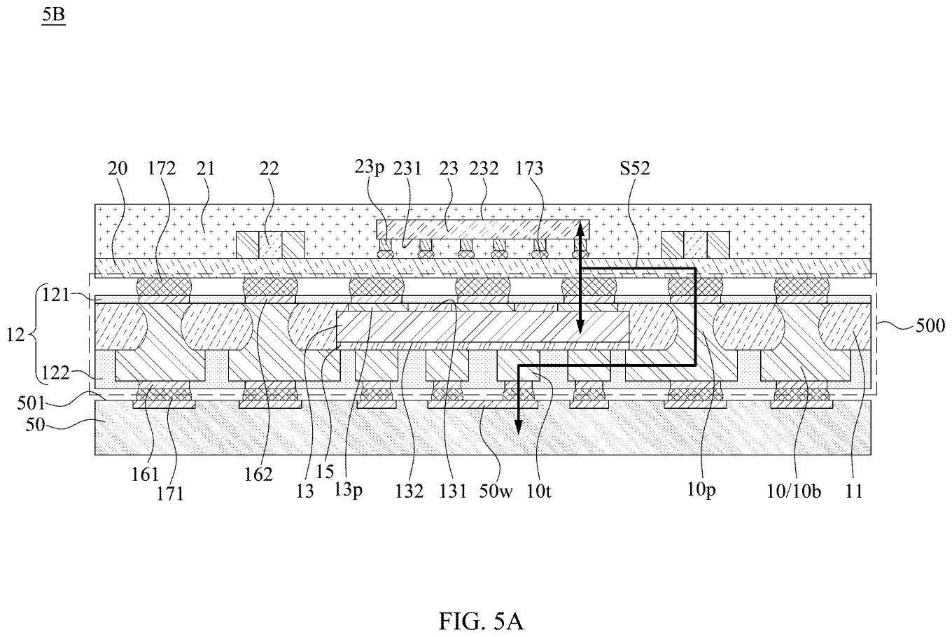

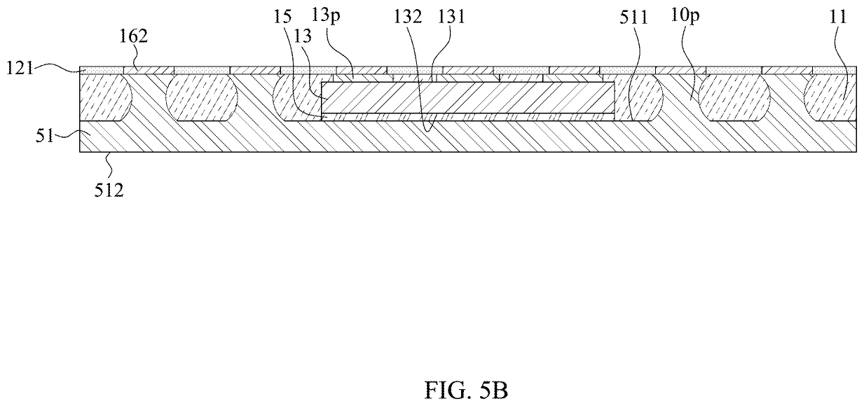

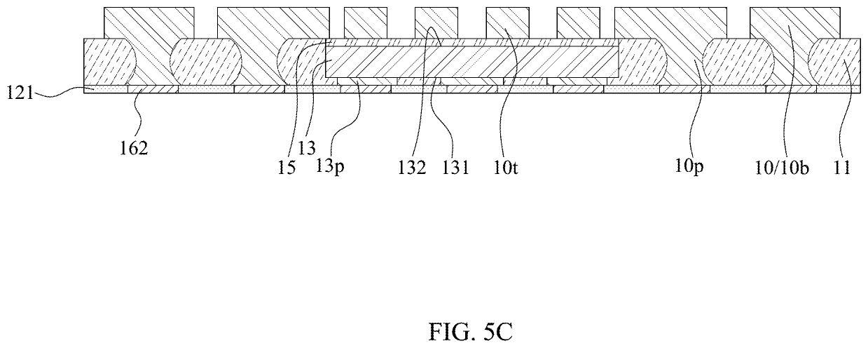

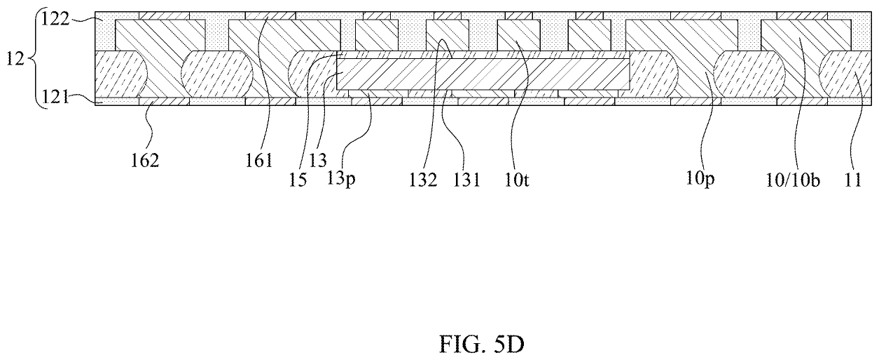

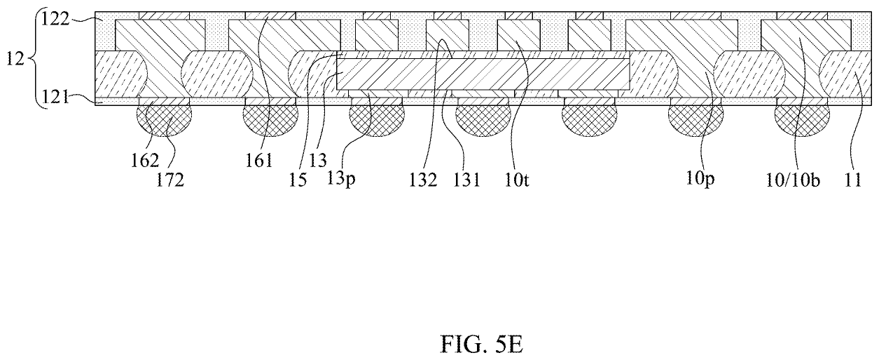

FIG. 5 illustrates a cross-sectional view of a semiconductor package structure 5A according to some embodiments of the present disclosure. The semiconductor package structure 5A in FIG. 5 is similar to the semiconductor package structure 1 in FIG. 1. Therefore, some detailed descriptions may refer to corresponding preceding paragraphs and are not repeated hereinafter for conciseness, with differences therebetween as follows.

The semiconductor package structure 5A may further include a wiring structure 50 disposed below the carrier 10 or the component 13, rather than the redistribution structure 14 in FIG. 1. The wiring structure 50 may be configured to electrically connect the component 13 (or the pads 13p) to the carrier 10 (or the conductive pillars 10p and the trace portion 10t). The wiring structure 50 may include a conductive trace 50w disposed at a surface (or an upper surface) 501 of the wiring structure 50. The surface 501 may face the carrier 10 or the component 13. The conductive trace 50w may have a pattern density compatible with that of the pads 13p of the component 13.

The carrier 10 (including the trace portion 10t, the base portion 10b, and the conductive pillars 10p), the dielectric layer 11, the protective layer 12, the component 13, the insulation layer 15, and the connection elements 172 may be collectively referred to as a semiconductor package structure 500 electrically connected to other systems, components, and devices stacked thereover.

The component 13 may be electrically connected to the component 23 through the trace portion 10t and the wiring structure 50. An electrical transmission path S51 may be established among the component 23, the carrier 20, the trace portion 10t, the conductive pillars 10p, the conductive trace 50w, and the component 13. The component 13 may be electrically connected to the component 23 through the conductive trace 50w of the wiring structure 50. Hence, the semiconductor package structure 5A realizes the electrical connection of the stacking components 13 and 23 without an additional redistribution structure. The manufacturing cost of the semiconductor package structure 5A can be reduced by eliminating the process for the formation of a redistribution structure. Furthermore, the semiconductor package structure 5A may be particularly attractive in the high voltage/current applications.

FIG. 5A illustrates a cross-sectional view of a semiconductor package structure 5B according to some embodiments of the present disclosure. The semiconductor package structure 5B in FIG. 5A is similar to the semiconductor package structure 5A in FIG. 5. Therefore, some detailed descriptions may refer to corresponding preceding paragraphs and are not repeated hereinafter for conciseness, with differences therebetween as follows.

The semiconductor package structure 500 is reversely disposed between the carrier 20 and the wiring structure 50, as compared to the arrangement as illustrated in FIG. 5. The trace portion 10t of the carrier 10 may face the wiring structure 50. The active surface 312 of the component 13 may face the carrier 20.

The wiring structure 50 may be electrically connected to the component 23 through the carrier 10 (or the trace portion 10t and the conductive pillars 10p). An electrical transmission path S52 may be established among the component 23, the carrier 20, the component 13, the conductive pillars 10p, the trace portion 10t, and the conductive trace 50w. The component 13 may be electrically connected to the component 23 through the carrier 20. The component 13 may be electrically connected to the wiring structure 50 through the conductive pillars 10p, and the trace portion 10t.

FIG. 5B, FIG. 5C, FIG. 5D, and FIG. 5E illustrate one or more stages of an example of a method for manufacturing a semiconductor package structure (or the semiconductor package structure 5A or 5B) according to some embodiments of the present disclosure. The stages of the method for manufacturing the semiconductor package structure 5A or 5B may include the stages as illustrated in FIGS. 1A, 1B, 1C, 1D, and 1E. The stages of FIG. 5B, FIG. 5C, FIG. 5D, and FIG. 5E may follow the stages of FIGS. 1A, 1B, 1C, 1D, and 1E.

Referring to FIG. 5B, a portion 121 of a protective layer is formed on the pads 13p of the component 13 and the conductive pillars 10p as shown in FIG. 1. A conductive layer 162 may be formed on pads 13p and the conductive pillars 10p. The conductive layer 162 may be surrounded by the portion 121.

Referring to FIG. 5C, the conductive base 51 is etched from the surface 512 to form a base portion 10b over the conductive pillar 10p and a trace portion 10t over the backside surface 132 of the component 13. The base portion 10b, the trace portion 10t, and the conductive pillars 10p may be referred to as a carrier 10. The trace portion 10t may include a plurality of sections separated from each other in the cross section of FIG. 5C. In some embodiments, one or more of the sections of the trace portion 10t may be connected. The trace portion 10t may be separated from the base portion 10b in the cross section of FIG. 5C. The trace portion 10t may be connected to the base portion 10b in another cross section. The base portion 10b may be connected to the conductive pillars 10p.

Referring to FIG. 5D, a portion 122 of the protective layer is formed on the trace portion 10t and the base portion 10b of the carrier 10. A conductive layer 161 may be formed on the trace portion 10t and the base portion 10b. The conductive layer 161 may be surrounded by the portion 122. The portions 121 and 122 may be collectively referred to as a protective layer 12.

Referring to FIG. 5E, a plurality of connection elements 172 may be formed on the conductive layer 162 to form a semiconductor package structure 500 of FIG. 5. The connection elements 172 may include a ball grid array.

Afterwards, a carrier 20 provided with an encapsulant 21, a passive component 22, and a component 23 may be bonded on the trace portion 10t and the base portion 10b of the carrier 10 and a wiring structure 50 provided with a conductive trace 50w may be bonded on the connection elements 172 to form a semiconductor package structure 5A as shown in FIG. 5. In some embodiments, the carrier 20 provided with the encapsulant 21, the passive component 22, and the component 23 may be bonded on the pads 13p of the component 13 and the conductive pillars 10p of the carrier 10 and the wiring structure 50 provided with a conductive trace 50w may be bonded on the trace portion 10t and the base portion 10b to form a semiconductor package structure 5B as shown in FIG. 5A.

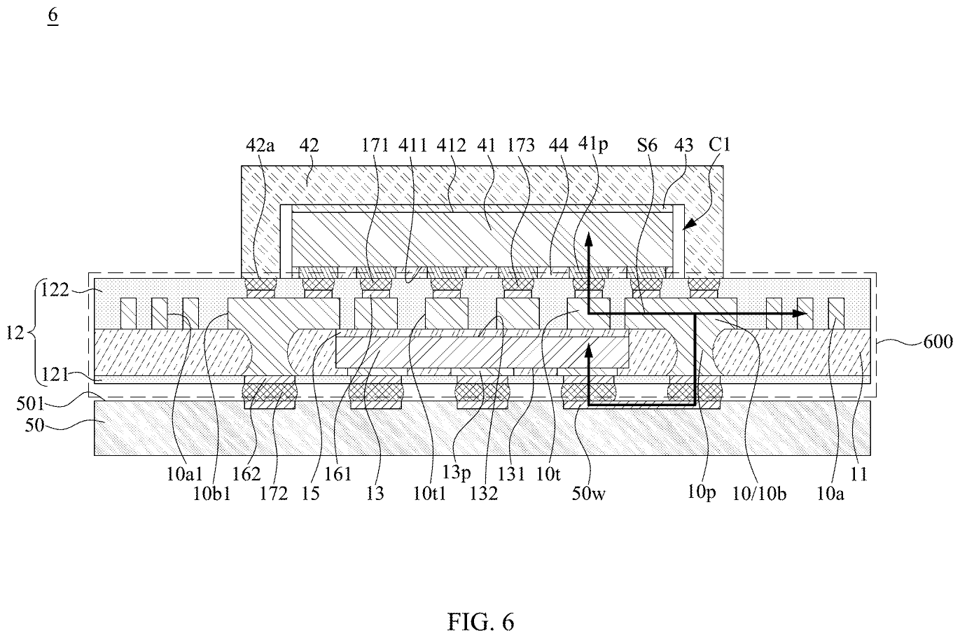

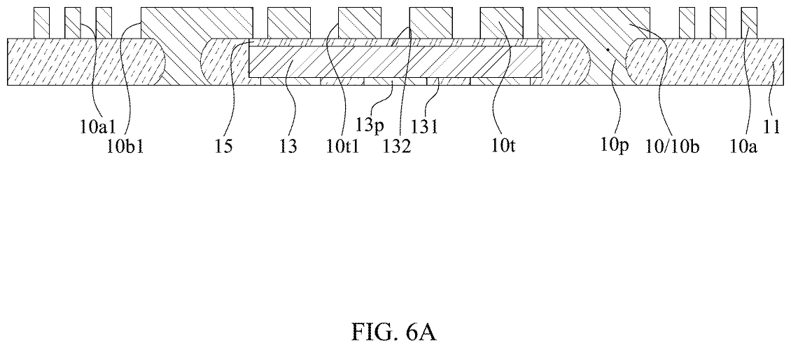

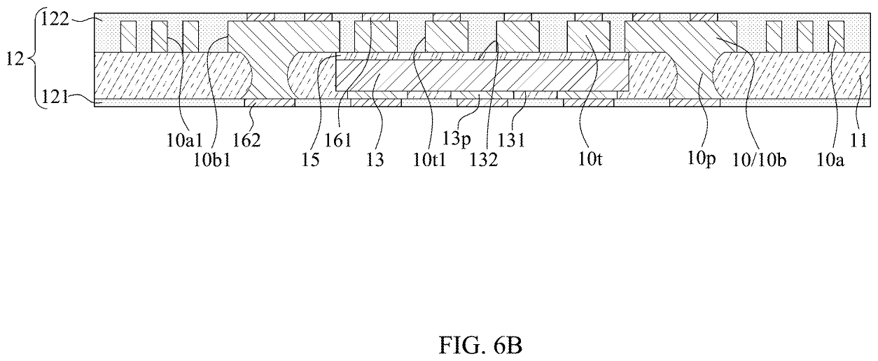

FIG. 6 illustrates a cross-sectional view of a semiconductor package structure 6 according to some embodiments of the present disclosure. The semiconductor package structure 6 in FIG. 6 is similar to the semiconductor package structure 4 in FIG. 4. Therefore, some detailed descriptions may refer to corresponding preceding paragraphs and are not repeated hereinafter for conciseness, with differences therebetween as follows.

The semiconductor package structure 6 may further include a wiring structure 50 disposed below the carrier 10 or the component 13, rather than the redistribution structure 14 in FIG. 4. The wiring structure 50 may be configured to electrically connect the component 13 (or the pads 13p) to the carrier 10 (or the conductive pillars 10p and the trace portion 10t). The wiring structure 50 may include a conductive trace 50w disposed at a surface (or an upper surface) 501 of the wiring structure 50. The surface 501 may face the carrier 10 or the component 13. The conductive trace 50w may have a pattern density compatible with that of the pads 13p of the component 13.

The carrier 10 (including the trace portion 10t, the base portion 10b, the conductive pillars 10p, and the antenna pattern 10a), the dielectric layer 11, the protective layer 12, the component 13, the insulation layer 15, and the connection elements 172 may be collectively referred to as a semiconductor package structure 600 electrically connected to other systems, components, and devices stacked thereover.

The component 13 may be electrically connected to the device 41 through the trace portion 10t and the wiring structure 50. An electrical transmission path S6 may be established among the device 41, the carrier 20, the trace portion 10t, the conductive pillars 10p, the conductive trace 50w, and the component 13. The electrical transmission path S6 may be further established between the component 13 and the antenna pattern 10a or the device 41 and the antenna pattern 10a. The component 13 may be electrically connected to the device 41 through the conductive trace 50w of the wiring structure 50. The antenna pattern 10a may be electrically connected to the component 13 or the device 41. Hence, the semiconductor package structure 5A realizes the electrical connection of the stacking component 13 and device 41 without an additional redistribution structure. The manufacturing cost of the semiconductor package structure 6 can be reduced by saving the process for the formation of a redistribution structure.

Forming the antenna pattern 10a by partial-etching the carrier 10 can efficiently utilize the side rail of the carrier. As such, the size of the semiconductor package structure 6 capable of receiving and transmitting a radiation signal can be relatively small.

FIG. 6A and FIG. 6B illustrate one or more stages of an example of a method for manufacturing a semiconductor package structure (e.g., the semiconductor package structure 6) according to some embodiments of the present disclosure. The stages of the method for manufacturing the semiconductor package structure 6 may include the stages as illustrated in FIGS. 1A, 1B, 1C, 1D, and 1E. The stages of FIG. 6A and FIG. 6B may follow the stages of FIGS. 1A, 1B, 1C, 1D, and 1E.

Referring to FIG. 6A, the conductive base 51 is etched from the surface 512 to form a base portion 10b over the conductive pillar 10p, a trace portion 10t over the backside surface 132 of the component 13, and an antenna pattern 10a. The base portion 10b, the trace portion 10t, the conductive pillars 10p, and the antenna pattern 10a may be referred to as a carrier 10. The trace portion 10t may include a plurality of sections separated from each other in the cross section of FIG. 6A. In some embodiments, one or more of the sections of the trace portion 10t may be connected. The trace portion 10t may be separated from the base portion 10b in the cross section of FIG. 6A. The trace portion 10t may be connected to the base portion 10b in another cross section. The base portion 10b may be connected to the conductive pillars 10p. The antenna pattern 10a may be further from the trace portion 10t than the base portion 10b. The conductive pillar 10p may be disposed between the trace portion 10t and the antenna pattern 10a.

Referring to FIG. 6B, a portion 121 of a protective layer 12 is formed on the pads 13p and the conductive pillars 10p, and the other portion 122 of the protective layer 12 is formed on the trace portion 10t, the base portion 10b, and the antenna pattern 10a of the carrier 10. A conductive layer 161 may be formed on the trace portion 10t and the base portion 10b. A conductive layer 162 may be formed on the pads 13p and the conductive pillars 10p. The conductive layers 161 and 162 may be surrounded by the protective layer 12. The stages of FIG. 5E may follow the stages of FIG. 6B. That is, a plurality of connection elements 172 may be formed on the conductive layer 162 to form a semiconductor package structure 600 of FIG. 6. The connection elements 172 may include a ball grid array.

Afterwards, a device 41 and a metal lid 42 may be bonded on the trace portion 10t and the conductive pillars 10p of the carrier 10 and a wiring structure 50 provided with a conductive trace 50w may be bonded on the connection elements 172 to form a semiconductor package structure 6 as shown in FIG. 6.

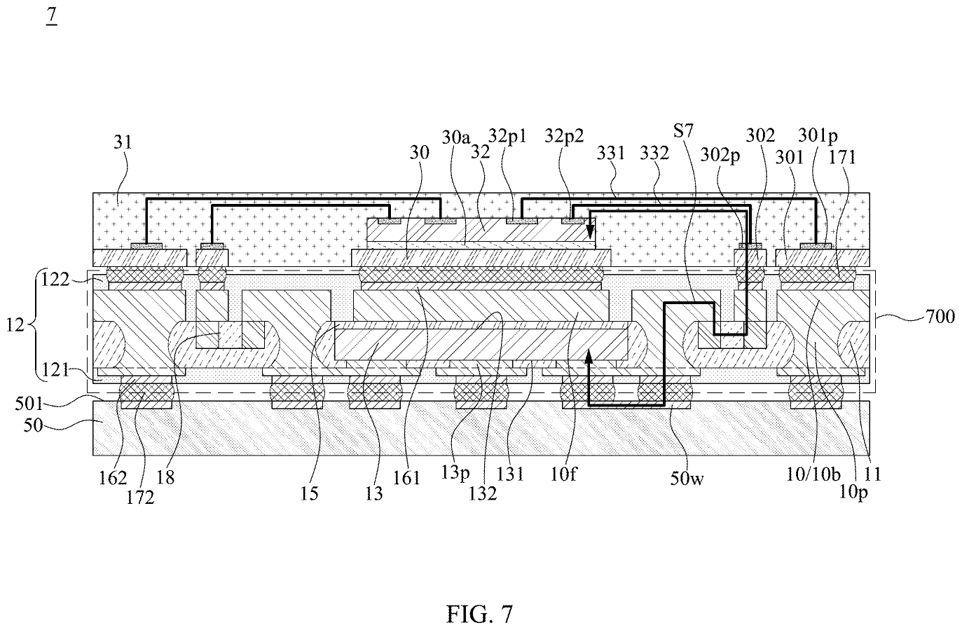

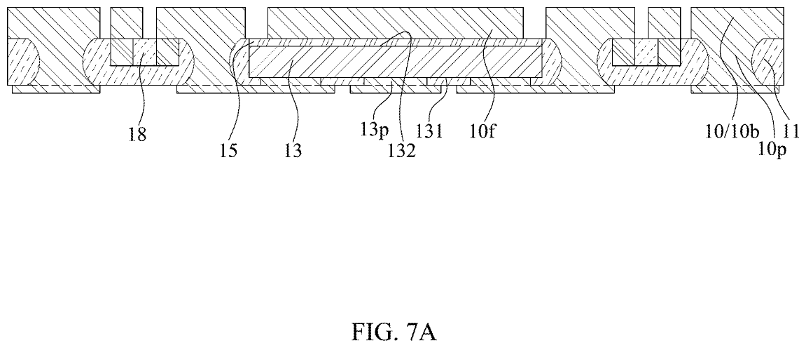

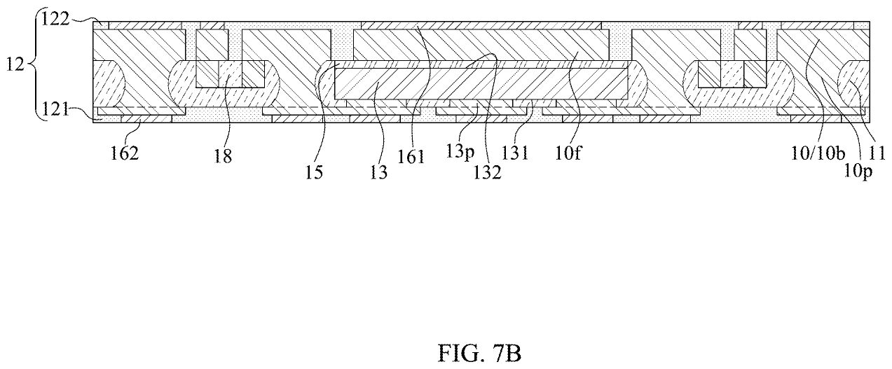

FIG. 7 illustrates a cross-sectional view of a semiconductor package structure 7 according to some embodiments of the present disclosure. The semiconductor package structure 7 in FIG. 7 is similar to the semiconductor package structure 3 in FIG. 3. Therefore, some detailed descriptions may refer to corresponding preceding paragraphs and are not repeated hereinafter for conciseness, with differences therebetween as follows.

The semiconductor package structure 7 may further include a wiring structure 50 disposed below the carrier 10 or the component 13, rather than the redistribution structure 14 in FIG. 3. The wiring structure 50 may be configured to electrically connect the component 13 (or the pads 13p) to the carrier 10 (or the conductive pillars 10p and the base portion 10b). The wiring structure 50 may include a conductive trace 50w disposed at a surface (or an upper surface) 501 of the wiring structure 50. The surface 501 may face the carrier 10 or the component 13. The conductive trace 50w may have a pattern density compatible with that of the pads 13p of the component 13.

The carrier 10 (including the landing portion 10f, the base portion 10b, and the conductive pillars 10p), the dielectric layer 11, the protective layer 12, the component 13, the insulation layer 15, the passive component 18, and the connection elements 172 may be collectively referred to as a semiconductor package structure 700 electrically connected to other systems, components, and devices stacked thereover.

The component 13 may be electrically connected to the component 32 through the conductive pillars 10p and base portion 10b of the carrier 10 and the wiring structure 50. An electrical transmission path S7 may be established among the component 32, the carrier 30, the base portion 10b, the passive component 18, the conductive pillar 10p, the conductive trace 50w, and the component 13. The component 13 may be electrically connected to the component 23 through the conductive trace 50w of the wiring structure 50. Hence, the semiconductor package structure 7 realizes the electrical connection of the stacking components 13 and 32 without an additional redistribution structure. The manufacturing cost of the semiconductor package structure 7 can be reduced by eliminating the process for the formation of a redistribution structure.

FIG. 7A and FIG. 7B illustrate one or more stages of an example of a method for manufacturing a semiconductor package structure (e.g., the semiconductor package structure 7) according to some embodiments of the present disclosure. The stages of the method for manufacturing the semiconductor package structure 7 may include the stages as illustrated in FIGS. 1A and 1B, as well as FIGS. 3A, 3B, and 3C. The stages of FIG. 7A and FIG. 7B may follow the stages of FIGS. 1A, 1B, 3A, 3B, and 3C.

Referring to FIG. 7A, the conductive base 51 is etched from the surface 512 to form a base portion 10b over the conductive pillar 10p and a landing portion 10f over the backside surface 132 of the component 13. The base portion 10b, the landing portion 10f, and the conductive pillars 10p may be referred to as a carrier 10. The passive component 18 may be configured to electrically connect to the base portion 10b and the conductive pillar 10p. The passive component 18 may have a terminal connected to a section of the base portion 10b and the other terminal connected to another section of the base portion 10b that connects the conductive pillar 10p.

Referring to FIG. 7B, a portion 121 of a protective layer 12 is formed on the pads 13p of the component 13 and the conductive pillars 10p, and the other portion 122 of the protective layer 12 is formed on the landing portion 10f and the base portion 10b of the carrier 10. A conductive layer 161 may be formed on the landing portion 10f and the base portion 10b. A conductive layer 162 may be formed on the pads 13p and the conductive pillars 10p. The conductive layers 161 and 162 may be surrounded by the protective layer 12. The stages of FIG. 5E may follow the stages of FIG. 7B. That is, a plurality of connection elements 172 may be formed on the conductive layer 162 to form a semiconductor package structure 700 of FIG. 7. The connection elements 172 may include a ball grid array.

Afterwards, a carrier 30 provided with an encapsulant 31 and a component 32 may be bonded on the landing portion 10f and the base portion 10b of the carrier 10 and a wiring structure 50 provided with a conductive trace 50w may be bonded on the connection elements 172 to form a semiconductor package structure 7 as shown in FIG. 7.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to +4%, less than or equal to +3%, less than or equal to +2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10+S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor package structure, comprising:
a carrier comprising a first part and a second part separated from the first part; and
a component disposed under the first part and electrically connected to the second part,
wherein the first part is configured to be electrically connected to a device disposed over the first part.

2. The semiconductor package structure of claim 1, wherein the first part comprises a trace portion extending in a direction parallel to a backside surface of the component.

3. The semiconductor package structure of claim 2, further comprising an insulation layer disposed between the trace portion and the backside surface of the component.

4. The semiconductor package structure of claim 3, wherein the trace portion of the first part comprises a plurality of sections separated from each other, and wherein at least one of the sections of the trace portion of the first part is exposed from the insulation layer.

5. The semiconductor package structure of claim 1, wherein the carrier comprises a third part disposed between the first part and the second part, and the semiconductor package structure further comprises a passive component disposed under the third part and the second part, and wherein the passive component is electrically connected the third part and the second part.

6. The semiconductor package structure of claim 1, wherein the second part is electrically connected to the device.

7. The semiconductor package structure of claim 1, further comprising a wiring structure disposed under the component, wherein the component is electrically connected to the device through the first part and the wiring structure.

8. A semiconductor package structure, comprising:
a carrier; and
a component disposed under the carrier and comprising a plurality of pads at an active surface of the component;
wherein the carrier comprises a trace portion disposed over a backside surface of the component, and
wherein the trace portion is electrically insulated from the backside surface of the component and electrically connected to the pads of the component.

9. The semiconductor package structure of claim 8, further comprising a redistribution structure disposed over the active surface of the component and electrically connected to the pads of the component and the trace portion of the carrier.

10. The semiconductor package structure of claim 9, wherein the carrier comprises a conductive pillar adjacent to the component and extending between the trace portion and the redistribution structure in a direction vertical to the backside surface of the component, and wherein the conductive pillar is electrically connected to the component through the redistribution structure.

11. The semiconductor package structure of claim 8, wherein the trace portion comprises a plurality of sections extending in a direction away from the component, wherein the sections of the trace portion are separated in a first cross section and connected in a second cross section.

12. The semiconductor package structure of claim 8, wherein the carrier comprises an antenna pattern non-overlapping with the component in a direction vertical to the backside surface thereof.

13. The semiconductor package structure of claim 12, wherein the carrier comprises a conductive pillar disposed between the trace portion and the antenna pattern, and configured to function as a shielding structure.

14. The semiconductor package structure of claim 9, wherein the component is electrically connected to a wafer level chip disposed over the carrier through the redistribution structure.

15. A semiconductor package structure, comprising:
a carrier; and
a component surrounded by the carrier;
wherein the carrier comprises an interconnection element adjacent to the component, and
wherein the interconnection element has a first tapered portion and a second tapered portion connected to the first tapered portion, wherein the first tapered portion and the second tapered portion taper in opposite directions.

16. The semiconductor package structure of claim 15, wherein the interconnection element has a central width smaller than a bottom width.

17. The semiconductor package structure of claim 15, wherein the interconnection element has a concave lateral surface.

18. The semiconductor package structure of claim 15, wherein the carrier comprises a base portion connected to the interconnection element, and a trace portion, and wherein the base portion is disposed around the trace portion.

19. The semiconductor package structure of claim 18, wherein a lateral surface of the base portion and a lateral surface of the trace portion have substantially the same roughness.

20. The semiconductor package structure of claim 15, further comprising a dielectric layer embedding the interconnection element and the component.
